(19) United States
(12) Patent Application Publication
(10) Pub. No.: US 2008/0116512 A1
(43) Pub. Date: May 22, 2008

(54) SEMICONDUCTOR DEVICE AND METHOD OF MAKING THE SAME

(75) Inventors: Yusuke Kawaguchi, Miura-gun (JP); Miwako Akiyama, Hachioji-shi (JP); Yoshihiro Yamaguchi, Saitama-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/943,181

(22) Filed: Nov. 20, 2007

(30) Foreign Application Priority Data
Nov. 21, 2006 (JP) 2006-314245
Sep. 11, 2007 (JP) 2007-235979

(51) Int. Cl. H01L 29/78; H01L 21/336

(52) U.S. Cl. 257/334; 438/270; 257/E21.41; 257/E29.262

(57) ABSTRACT

A semiconductor device includes a first conductivity type layer and a second conductivity type layer, which are alternately and repeatedly positioned, adjacent to each other, in a column-like fashion on a first conductivity type substrate. The balance of the net charge amount of the impurity between the first conductivity type layer formed under a second conductivity type base layer in the termination region of the semiconductor device and the second conductivity type layer adjacent to the first conductivity type layer is imbalanced in comparison to the balance of the net charge amount of the impurity between the first conductivity type layer in the device-forming region of the semiconductor device and the second conductivity type layer adjacent to the first conductivity type layer.

### CROSS REFERENCE TO RELATED APPLICATIONS

This application is based on and claims the benefit of priority from prior Japanese Patent Application No. 2006-314245, filed on Nov. 21, 2006, and No. 2007-235979, filed on Sep. 11, 2007, the entire contents of which are incorporated herein by reference.

### BACKGROUND OF THE INVENTION

1. Field of the Invention

The present invention relates to a semiconductor device and method of making the same, and more particularly to an invention for improving the avalanche withstanding capability.

2. Description of the Related Art

Recent years have seen a significant market expansion of power MOS transistors in the field of reduced energy switching including a high-breakdown-voltage switching supply, a mobile communication device, and the like. Since the power MOS transistors are used in power management circuits, safety circuits in lithium-ion batteries, and so on, it is required to have an improved breakdown voltage, a lower driving voltage, a lower on-resistance, and a reduced switching loss.

The on-resistance of power MOS transistors is mainly composed of a channel resistance and a drift resistance. Conventionally, a super junction structure is known as a structure for providing a reduced resistance in a drift layer, in which p-type layers and n-type layers are alternately positioned. The super junction structure provides a lower on-resistance exceeding the material limit by creating a pseudo non-doped layer and retaining a high breakdown voltage, while applying the current through a highly-doped n-type column layer, with equal net charge amount (total net charge) of the impurity contained in the p-type column layer and the n-type column layer. In order to retain the breakdown voltage, accurate control is needed for each impurity amount in the n-type column layer and the p-type column layer.

However, if a semiconductor device with such a super junction structure is used as a switching device for inductive loads, a diode configured by a p-type base layer and a highly-concentrated n-type drift layer would be reverse-biased by a back electromotive force generated by the inductive load when an inductive load is turned off.

Further, an n⁺ type source layer, a p-type base layer and an n⁺ type semiconductor substrate (a drain) forms a parasitic n-p-n transistor. The n⁺ type source layer serves as an emitter, the p-type base layer as a base, and the n⁺ type semiconductor substrate as a collector. If this parasitic n-p-n transistor is turned on during avalanche breakdown occurs, generating some current locally in a device-forming region and thus destroying the device (see, Japanese Patent Laid-Open No. 2004-319732).

### SUMMARY OF THE INVENTION

A semiconductor device according to one aspect of the present invention comprises: a first conductivity type layer and a second conductivity type layer, each being alternately and repeatedly positioned, adjacent to each other, in a column-like fashion on a first conductivity type substrate; a second conductivity type base layer formed on the first conductivity type layer and the second conductivity type layer; a trench formed so as to extend from a surface of the second conductivity type base layer to the first conductivity type layer; a gate insulation film formed on the side surfaces and the bottom surface of the trench; a gate electrode formed inside the trench via the gate insulation film; an interlayer insulating film formed on the gate electrode; a first conductivity type diffusion layer formed on the surface of the second conductivity type base layer; a first main electrode formed on the first conductivity type diffusion layer; a second main electrode formed on the bottom surface of the first conductivity type substrate; a device-forming region in which the first conductivity type diffusion layer is formed; and a termination region provided around the circumference of the device-forming region and not including the first conductivity type diffusion layer formed therein, wherein the balance of the net charge amount of the impurity between the first conductivity type layer formed under the second conductivity type base layer in the termination region and the second conductivity type layer adjacent to the first conductivity type layer is imbalanced in comparison to the balance of the net charge amount of the impurity between the first conductivity type layer in the device-forming region and the second conductivity type layer adjacent to the first conductivity type layer.

A method for making a semiconductor device according to one aspect of the present invention comprises: forming a first conductivity type layer on a first conductivity type substrate by epitaxial growth; forming a second conductivity type base layer by injecting and diffusing second conductivity type impurity into a surface of the first conductivity type layer; forming a trench so as to extend from the surface of the second conductivity type base layer to the first conductivity type layer; forming a gate insulation film on the side surfaces and the bottom surface of the trench; forming a gate electrode inside the trench via the gate insulation film; forming an interlayer insulating film on the gate electrode; depositing a processing film over the first conductivity type layer in which the second conductivity type base layer is formed; forming a first aperture in the processing film on a device-forming region, and forming a second aperture in the processing film on a termination region provided around the circumference of the device-forming region; performing ion implantation on the first conductivity type layer, so that the balance of the net charge amount of the impurity between a second conductivity type layer formed under the second conductivity type base layer in the termination region using the processing film as a mask and the first conductivity type layer adjacent to the second conductivity type layer becomes imbalanced in comparison to the balance of the net charge amount of the impurity between a second conductivity type layer formed under the second conductivity type base layer in the device-forming region and the first conductivity type layer adjacent to the second conductivity type layer; performing ion implantation on the second conductivity type base layer on the device-forming region to form a first conductivity type diffusion layer; forming a first main electrode on the first conductivity type diffusion layer; and forming a second main electrode on the bottom surface of the first conductivity type substrate.

Further, a semiconductor device according to another aspect of the present invention comprises: a first conductivity type layer and a second conductivity type layer, each being alternately and repeatedly positioned, adjacent to each other, in a column-like fashion on a first conductivity type substrate; a second conductivity type base layer formed on the first conductivity type layer and the second conductivity type layer; a trench formed so as to extend from a surface of the second conductivity type base layer to the first conductivity type layer; a gate insulation film formed on the side surfaces and the bottom surface of the trench; a gate electrode formed inside the trench via the gate insulation film; an interlayer insulating film formed on the gate electrode; a first conductivity type diffusion layer formed on the surface of the second conductivity type base layer; a first main electrode formed on the first conductivity type diffusion layer; a second main electrode formed on the bottom surface of the first conductivity type substrate; a device-forming region in which the first conductivity type diffusion layer is formed; and a termination region provided around the circumference of the device-forming region and not including the first conductivity type diffusion layer formed therein; wherein the second conductivity type base layer in the device-forming region has a higher second conductivity type impurity concentration in a position far from the trench than in the vicinity of the trench.

### BRIEF DESCRIPTION OF THE DRAWINGS

FIG. 1 illustrates a longitudinal sectional view of a semiconductor device according to a first embodiment of the present invention;

FIG. 2 is a process diagram illustrating a method for making the semiconductor device according to the first embodiment of the present invention;

FIG. 3 is a process diagram illustrating a method for making the semiconductor device according to the first embodiment of the present invention;

FIG. 4 is a process diagram illustrating a method for making the semiconductor device according to the first embodiment of the present invention;

FIG. 5 is a process diagram illustrating a method for making the semiconductor device according to the first embodiment of the present invention;

FIG. 6 is a process diagram illustrating a method for making the semiconductor device according to the first embodiment of the present invention;

FIG. 7 is a process diagram illustrating a method for making the semiconductor device according to the first embodiment of the present invention;

FIG. 8 illustrates a longitudinal sectional view of another exemplary semiconductor device according to the first embodiment of the present invention;

FIG. 9 illustrates a longitudinal sectional view of the semiconductor device according to a second embodiment of the present invention;

FIG. 10 is a process diagram illustrating a method for making the semiconductor device according to the second embodiment of the present invention;

FIG. 11 illustrates a longitudinal sectional view of a semiconductor device according to a third embodiment of the present invention; and

FIG. 12 illustrates an impurity concentration distribution at X-X′ cross-section in the semiconductor device according to the third embodiment of the present invention.

### DETAILED DESCRIPTION OF THE EMBODIMENTS

Now, embodiments of the present invention will be described below with reference to the accompanying drawings.

### First Embodiment

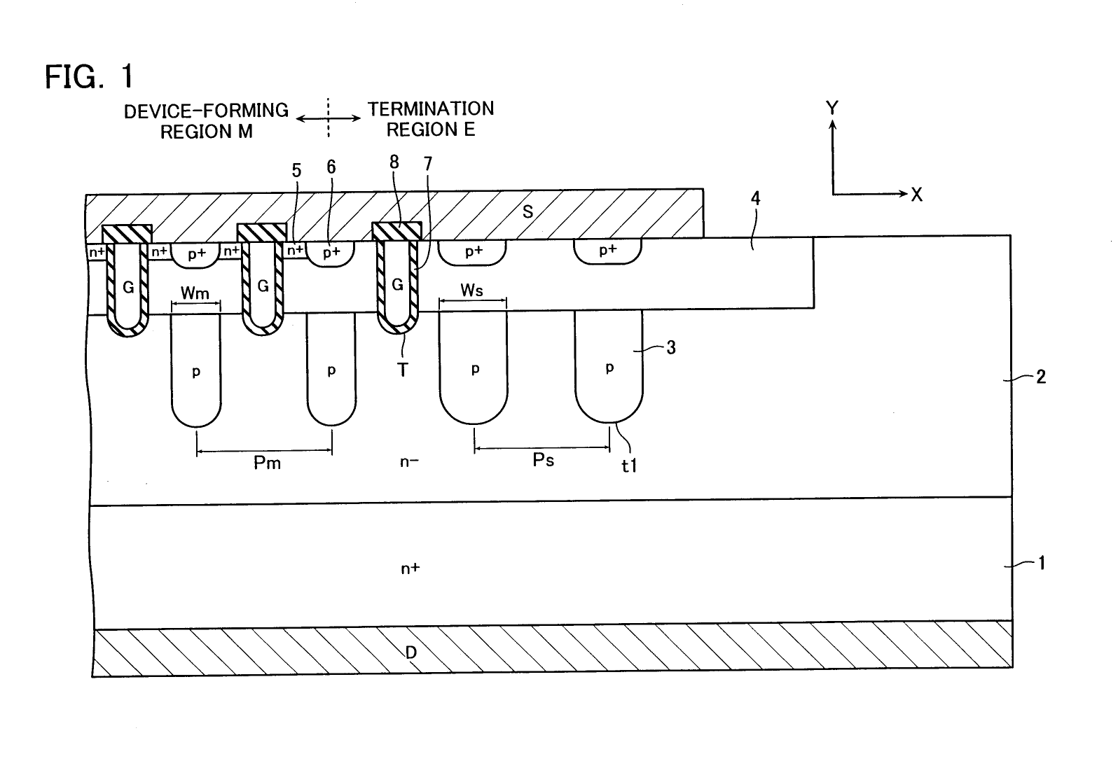

FIG. 1 illustrates a longitudinal sectional view of a structure of a trench MOS transistor according to a first embodiment of the present invention.

In addition, the longitudinal sectional view illustrates a termination region of the n-channel type trench MOS transistor. The present invention is applied to an n-channel type trench MOS transistor with a super junction structure in the first embodiment. As used herein, the term “p⁺ type” refers to a semiconductor with high p-type impurity concentration; and “p⁻ type” refers to a semiconductor with low p-type impurity concentration. Similarly, “n⁺ type” refers to a semiconductor with high n-type impurity concentration; and “n⁻ type” refers to a semiconductor with low n-type impurity concentration.

As illustrated in FIG. 1, in the semiconductor device according to this embodiment, an n⁻ type epitaxial layer 2 is formed on an n⁺ type semiconductor substrate 1. Provided in the n⁻ type epitaxial layer 2 are p-type column layers 3, which are repeatedly formed in a column-like fashion. That is, the p-type column layers 3 and those portions of the n⁻ type epitaxial layer 2 formed therebetween are positioned adjacent to each other in a column-like fashion. Further, a p-type base layer 4 is formed on, and in connection with, the repeatedly formed p-type column layers 3 and the column-shaped portions of the n⁻ type epitaxial layer 2 formed therebetween. Moreover, an n⁺ type source layer 5 and a p⁺ type high concentration layer 6 is selectively formed on a surface of the p-type base layer 4 in connection with the p-type column layers 3 via the p-type base layer 4.

In addition, a trench T is formed on the surface of the p-type base layer 4 that extends to the inside of the n⁻ type epitaxial layer 2. A gate insulation film 7 is formed on the side surfaces and the bottom surface of the trench T. A gate electrode G is embedded inside the gate insulation film 7. Further, an interlayer insulating film 8 is formed on the gate electrode G. Moreover, a source electrode S is formed on the p-type base layer 4 so that it electrically contacts with the p-type column layers 3 via the p-type base layer 4 and electrically connects to the n⁺ type source layer 5 and the p⁺ type high concentration layer 6. A drain electrode D is formed on the bottom surface of the n⁺ type semiconductor substrate 1.

Next, in the device-forming region M of the semiconductor device illustrated in the left side of the drawing, the n⁺ type source layer 5 is formed in the surface of the p-type base layer 4, which forms a semiconductor device with an n-p-n junction in a vertical direction (Y-direction). Further, the device-forming region M is formed in such a way that the net impurity total in the p-type column layers 3 and the net impurity total in the column-shaped portions of the n⁻ type epitaxial layer 2 adjacent to the p-type column layers 3 (also referred to as an “n-type column layer”) are substantially equal-balanced. That is, the p-type column layers 3 and the column-shaped portions of the n⁻ type epitaxial layer 2 adjacent to the p-type column layers 3 (the n-type column layer) are formed so as to be substantially charge-balanced.

On the other hand, in the termination region E illustrated in the right side of the drawing, the n⁺ type source layer 5 is not formed and there is no semiconductor device with an n-p-n junction in a vertical direction (Y-direction). In addition, the array pitch Ps in X-direction of the p-type column layers 3 formed in the termination region E is configured to be equal to the array pitch Pm in X-direction of the column layer 3 in the device-forming region M. The width Ws in X-direction of the p-type column layers 3 formed in the termination region E is configured to be longer than the width Wm in X-direction of the column layer 3 in the device-forming region M.

Further, in this embodiment, in both of the device-forming region M and the termination region E, each p-type column layer 3 has the same impurity concentration, and each portion of the n⁻ type epitaxial layer 2 adjacent to each of the p-type column layer 3 has the same impurity concentration. That is, each p-type column layer 3 in the termination region E and each portion of the n⁻ type epitaxial layer 2 (the n-type column layer) adjacent to the p-type column layers 3 are imbalanced in their net charge amount of the impurity in comparison to the net charge balance between each p-type column layer 3 in the device-forming region M and each portion of the n⁻ type epitaxial layer 2 (the n-type column layer) adjacent to the p-type column layers 3.

Now, a method for making the semiconductor device so configured will be generally described below. At first, with an epitaxial growth method, an n⁻ type epitaxial layer 2 is formed on an n⁺ type semiconductor substrate 1, which is a highly-concentrated substrate.

Then, an oxide film is deposited on a surface of the n⁻ type epitaxial layer 2 for patterning, and etching is performed to form a trench t1. At this moment, with respect to the aperture width of the trench t1, the aperture width of the trench t1 in the termination region E (Ws) is formed to be larger than the aperture width of the trench t1 in the device-forming region M (Wm). Then, a p-type epitaxial layer is filled into the trench t1 to form a p-type column layer 3.

Then, a p-type impurity such as boron is introduced by ion implantation into the surface of the n⁻ type epitaxial layer 2 where the p-type column layer 3 is formed, thereby forming a p-type base layer 4. Moreover, another oxide film is deposited on the top surface of the p-type base layer 4 for patterning, and certain portions of the oxide film are removed until the silicon surface is exposed. Using the patterned oxide film as a mask, a trench T is formed that extends to the inside of the n⁻ type epitaxial layer 2. Then, a gate insulation film 7 is formed by a plasma CVD method or the like.

Further, polysilicon is embedded inside the trench T via the gate insulation film 7 to form a gate electrode G. After that, an interlayer insulating film 8 is deposited on the top surface of the gate electrode G. Then, each interlayer insulating film 8 is removed that is positioned between the gate electrodes G. Then, the n⁺ type source layer 5 and the p⁺ type high concentration layer 6 are selectively formed by ion implantation. Then, a source electrode S is formed by spattering a source metal, and a drain electrode D is provided by forming a drain metal on the rear surface. The semiconductor device illustrated in FIG. 1 is made according to the above-mentioned method.

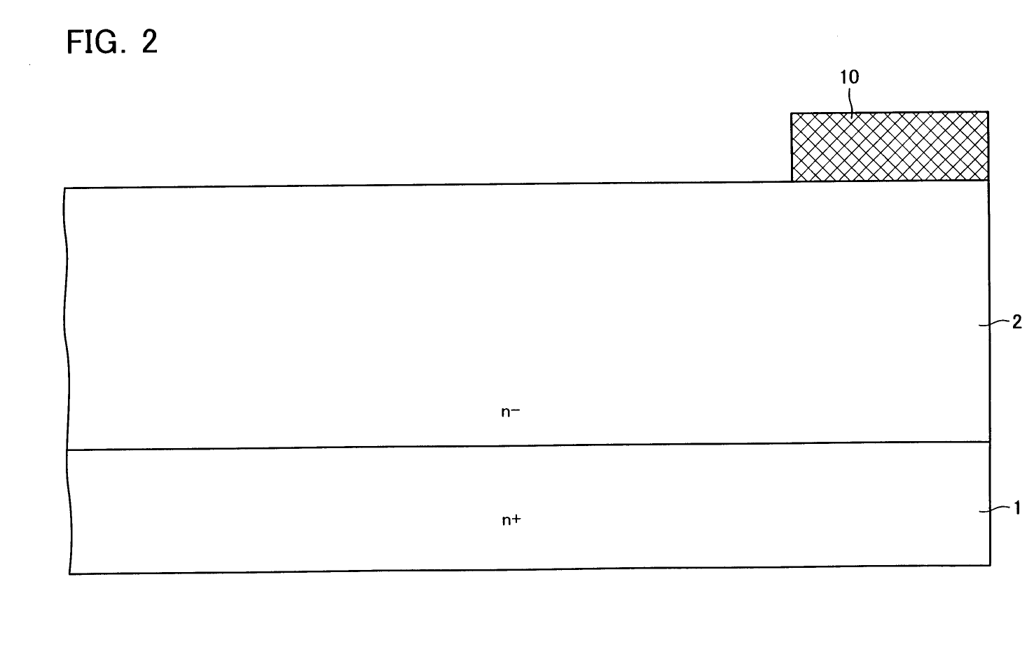

Now, another method for making the semiconductor device according to the first embodiment of the present invention will be described below with reference to the drawings. FIGS. 2 through 7 are process diagrams illustrating a method for making the trench MOS transistor according to the first embodiment.

At first, by an epitaxial growth method, an n⁻ type epitaxial layer 2 is formed on a highly-concentrated n⁺ type semiconductor substrate 1. Then, a mask 10 is selectively formed on a surface of the n⁻ type epitaxial layer 2. In this embodiment, the impurity concentration of the n⁻ type epitaxial layer 2 under the device-forming region M is equal to that under the termination region E (see FIG. 2).

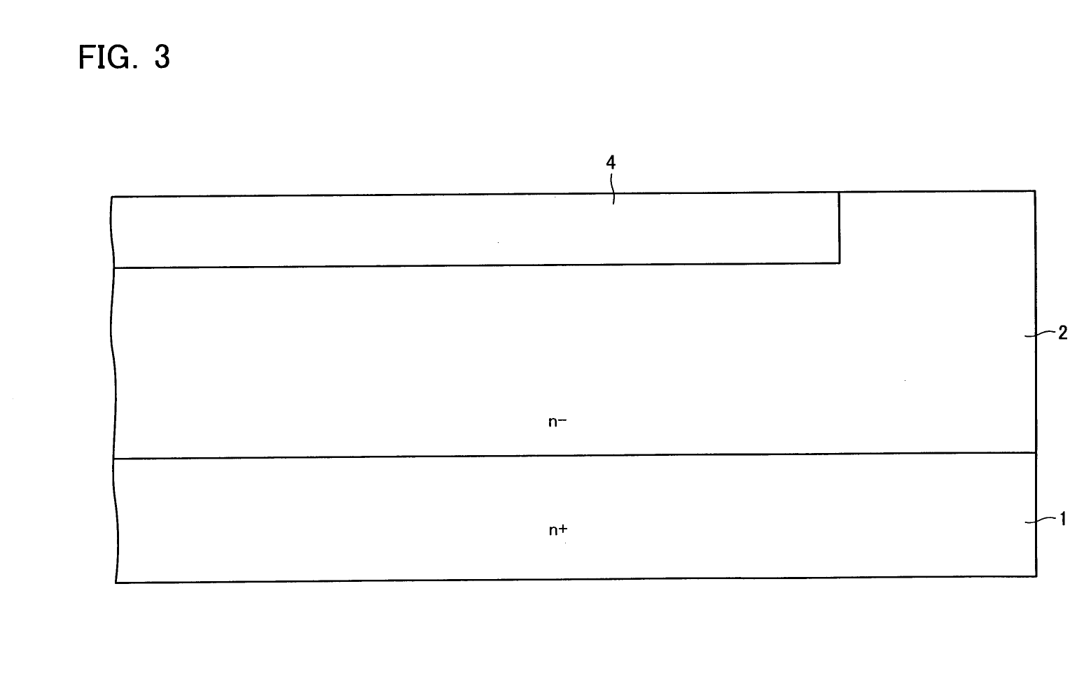

Then, a p-type impurity such as boron is injected into the surface of the n⁻ type epitaxial layer 2, on which the mask 10 is formed. Then, the mask 10 is removed and a p-type base layer 4 is formed by diffusing boron by a heating process or the like (see FIG. 3).

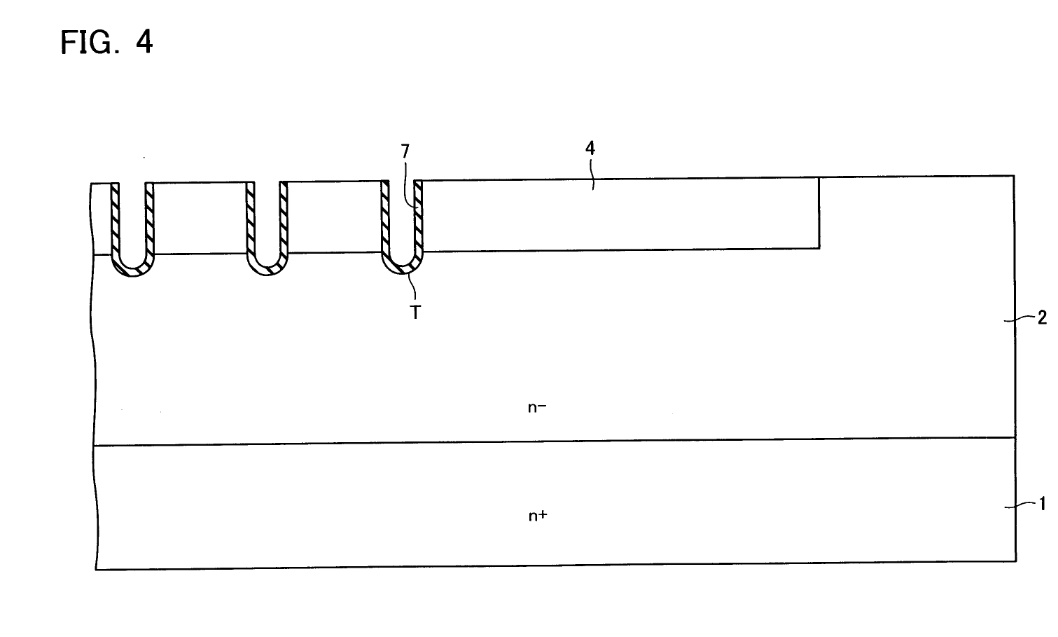

Moreover, an oxide film is deposited on the top surface of the p-type base layer 4 for patterning, and certain portions of the oxide film are removed until the silicon surface is exposed. Using the patterned oxide film as a mask, a trench T is formed that extends to the inside of the n⁻ type epitaxial layer 2. After the trench T is formed, the oxide film is removed and a gate insulation film 7 is formed on the bottom surface and side walls of the trench T with a plasma CVD method or the like (see FIG. 4).

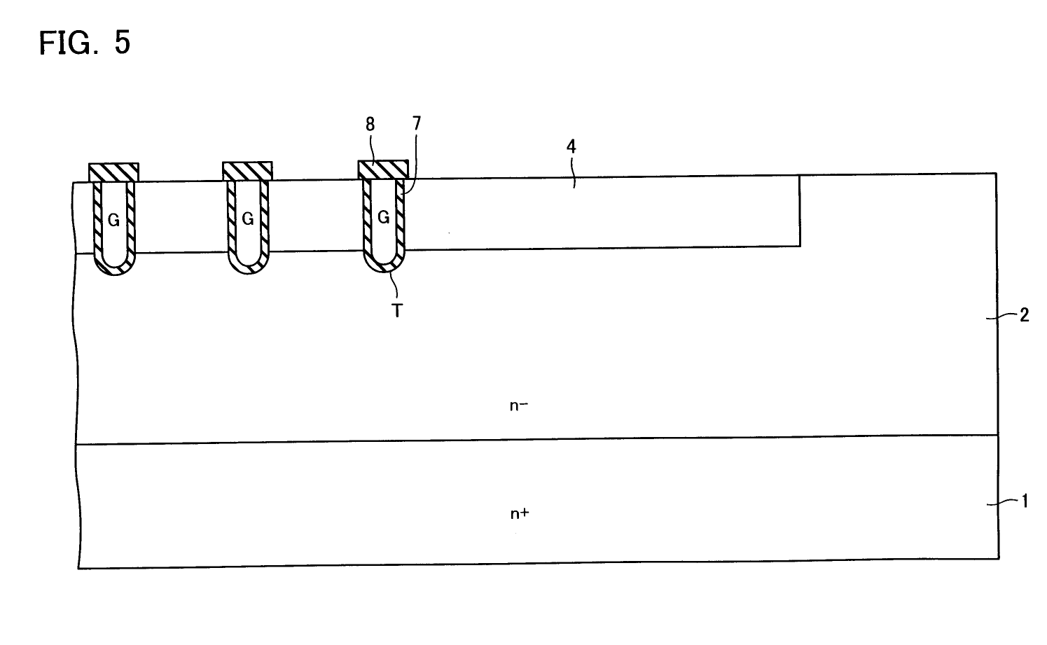

Then, polysilicon is embedded inside the trench T via the gate insulation film 7 to form a gate electrode G. After that, an interlayer insulating film 8 is deposited on the top surface of the gate electrode G. Then, each interlayer insulating film 8 is removed that is positioned between the gate electrodes G (see FIG. 5).

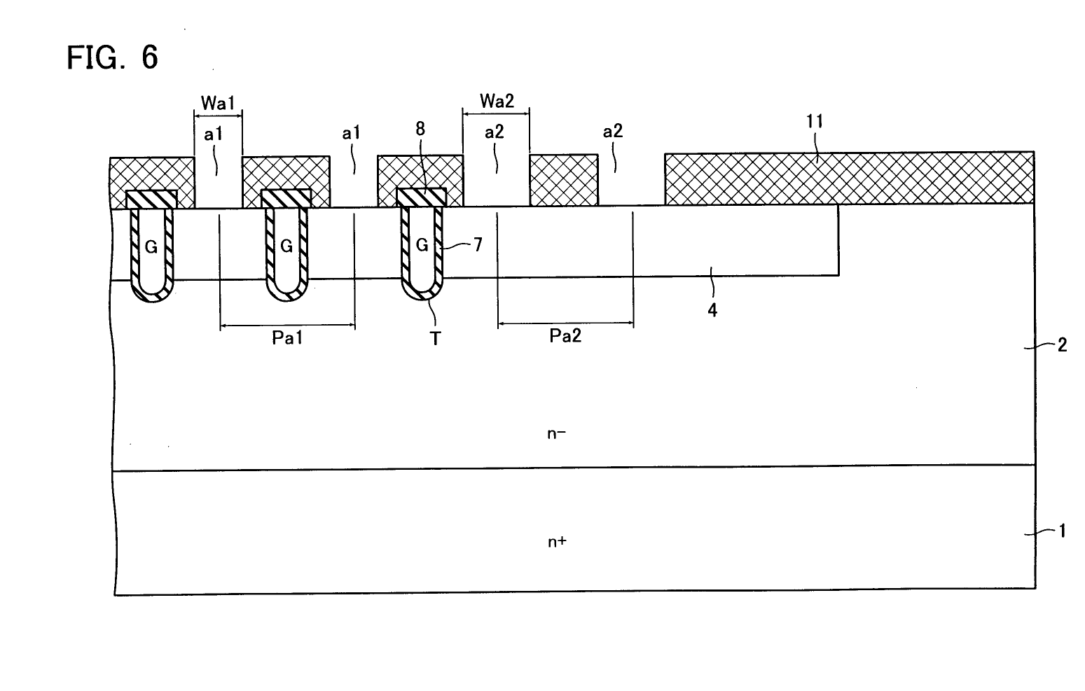

Then, an oxide film 11 is deposited over the entire surface of the n⁻ type epitaxial layer 2 including the p-type base layer 4 for patterning and etching is performed to form an aperture a1 on the device-forming region M and an aperture a2 on the termination region E. According to the method for making the semiconductor device according to this embodiment, the aperture width Wa2 of the aperture a2 (corresponding to the aperture width of the trench Ws in the termination region E) is formed to be larger than the aperture width Wa1 of the aperture a1 (corresponding to the aperture width of the trench Wm in the device-forming region M). Further, the array pitch Pa1 of the aperture a1 formed on the device-forming region M is equal to the array pitch Pa2 of the aperture a2 formed on the termination region E (see FIG. 6).

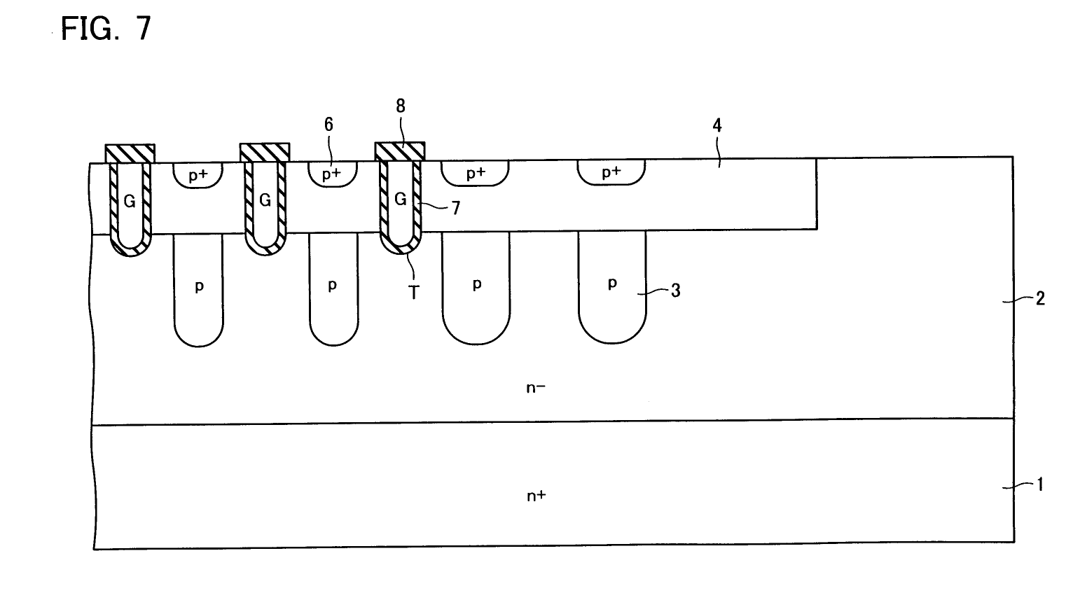

Using the oxide film 11 as a mask, ion implantation is performed into then⁻ type epitaxial layer 2. Further, using the same oxide film 11 as a mask, ion implantation is performed into the p-type base layer 4 with a different speed. After the oxide film 11 is removed, for example, ion is diffused with heating process to form a p-type column layer 3 in the n⁻ type epitaxial layer 2 and a p⁺ type high concentration layer 6 in the p-type base layer 4. In this embodiment, the impurity concentration of each p-type column layer 3 under the device-forming region M is equal to that under the termination region E (see FIG. 7).

Then, ion implantation is performed into the p-type base layer 4 in the device-forming region M, and an n⁺ type source layer 5 is selectively formed thereon. Then, a source electrode S is spattered on the p-type base layer 4. Thereafter, etching is performed to form the source electrode S. In addition, after the rear surface of the n⁺ type semiconductor substrate 1 is polished, a drain electrode D is provided accordingly. The semiconductor device illustrated in FIG. 1 may also be made according to the above-mentioned method, wherein the balance of the net charge amount of the impurity in the termination region E between the p-type column layers 3 and the portions of the n⁻ type epitaxial layer 2 (the n-type column layer) is imbalanced in comparison to the balance of the net charge amount of the impurity in the device-forming region M between the p-type column layers 3 and the portions of the n⁻ type epitaxial layer 2 (the n-type column layer).

As described above, the method for making a semiconductor device according to this aspect comprises: forming a first conductivity type layer on a first conductivity type substrate by epitaxial growth; forming a second conductivity type base layer by injecting and diffusing a second conductivity type impurity into a surface of the first conductivity type layer; forming a trench so as to extend from the surface of the second conductivity type base layer to the first conductivity type layer; forming a gate insulation film on the side surfaces and the bottom surface of the trench; forming a gate electrode inside the trench via the gate insulation film; forming an interlayer insulating film on the gate electrode; depositing a processing film on the first conductivity type layer in which the second conductivity type base layer is formed; forming a first aperture in the processing film on a device-forming region, and forming a second aperture in the processing film on a termination region provided around the circumference of the device-forming region; performing ion implantation on the first conductivity type layer, so that the balance of the net charge amount of the impurity between a second conductivity type layer formed under the second conductivity type base layer in the termination region using the processing film as a mask and the first conductivity type layer adjacent to the second conductivity type layer becomes imbalanced in comparison to the balance of the net charge amount of the impurity between a second conductivity type layer formed under the second conductivity type base layer in the device-forming region and the first conductivity type layer adjacent to the second conductivity type layer; performing ion implantation on the second conductivity type base layer on the device-forming region to form a first conductivity type diffusion layer; forming a first main electrode on the first conductivity type diffusion layer; and forming a second main electrode on the bottom surface of the first conductivity type substrate.

In this method for making a semiconductor device, the balance of the net charge amount of the impurity between the second conductivity type layer and the first conductivity type layer in the termination region may be imbalanced in comparison to the balance of the net charge amount of the impurity between the second conductivity type layer and the first conductivity type layer in the device-forming region, providing a difference between a first width of a first aperture formed in the processing film on the device-forming region and a second width of a second aperture formed in the processing film on the termination region.

Then, when the MOS transistor so obtained is brought into a turn-off operation, a gate and a source are shortened to set a gate-source voltage VGS to 0V. Then, the gate-source voltage VGS is set to a value lower than a transistor threshold to exclude the channel.

At this moment, although the current path is blocked and the drain current turns to 0 A, this current change would cause a load with inductance to generate a back electromotive force, if an inductive load is connected to the MOS transistor. As a result, a back electromotive force is applied to the drain, which causes a reverse-biased state in a diode including the n⁻ type epitaxial layer 2 and the p-type base layer 4, thereby causing a breakdown.

As such, there is configured in the above-mentioned MOS transistor a parasitic bipolar transistor with an n-p-n junction that includes the n⁺ type source layer 5, p-type base layer 4 and n⁺ type semiconductor substrate 1 as an emitter, base and collector, respectively. As described above, due to the breakdown generated at the time of turn-off, an electron current flows into the n⁺ type semiconductor substrate 1 and a hole current flows into the p⁺ type high concentration layer 6 via the p-type base layer 4. When the potential of the p-type base layer 4 becomes high due to the voltage drop at the time of the hole current flowing through the p-type base layer 4, the junction between the p-type base layer 4 and the n⁺ type source layer 5 is forward-biased. This results in the injection of a hole into the n⁺ type source layer 5, turning the bipolar transistor with such an n-p-n junction “ON”.

As a result, the current is locally concentrated in the bipolar transistor during avalanche breakdown occurs, thereby causing a device destruction. However, in this embodiment, the p-n net charge balance in the termination region E would be imbalanced in comparison to the p-n net charge balance in the device-forming region M, as the column layer 3 with wider width than the device-forming region M is formed in the termination region E in connection with the source electrode S via the p-type base layer 4. Thus, the breakdown voltage in the termination region E is lower than that in the device-forming region M.

Therefore, the breakdown voltage generated between a source and a drain is applied to the termination region E with lower resistance, which has an imbalanced p-n net charge in comparison to that in the device-forming region M, and also has the p-type column layers 3 and the column-shaped portions of the n⁻ type epitaxial layer 2 connected to the source electrode S via the p-type base layer 4. In addition, the current only flows into the termination region E without any parasitic n-p-n transistor.

As a result, since any current may be prevented from being locally generated in the n-p-n bipolar transistor in the device-forming region M and the avalanche breakdown may also be suppressed, the avalanche withstanding capability may be improved in the entire semiconductor device.

In addition, although the first embodiment has been described with reference to an exemplary n-channel type trench MOS transistor, the present invention may equally be applied to p-channel type trench MOS transistors by providing a difference between the width Wm and Ws of each p-type column layer 3.

Further, in the first embodiment, although the net charge balance in the termination region E is configured to be imbalanced in comparison to the net charge balance in the device-forming region M by providing a difference in the width of the column layer 3 between the device-forming region M and the termination region E, the advantages of the present invention may also be obtained from any different configurations that may change the net charge balance in the termination region E in a similar way.

For example, if the p-type impurity concentration in the p-type column layers 3 is substantially equal to the n-type impurity concentration in the n⁻ type epitaxial layer 2, the width of the p-type column layer 3 in the termination region E may be larger than the width of the adjacent column-shaped portion of the n⁻ type epitaxial layer 2 (the n-type column layer), or vice versa.

Further, the net charge balance in the termination region E may be imbalanced in comparison to the net charge balance in the device-forming region M by varying the impurity concentration for the device-forming region M and the termination region E. In this case, for the impurity concentration, the p-type impurity concentration may be larger than the n-type impurity concentration, or vice versa.

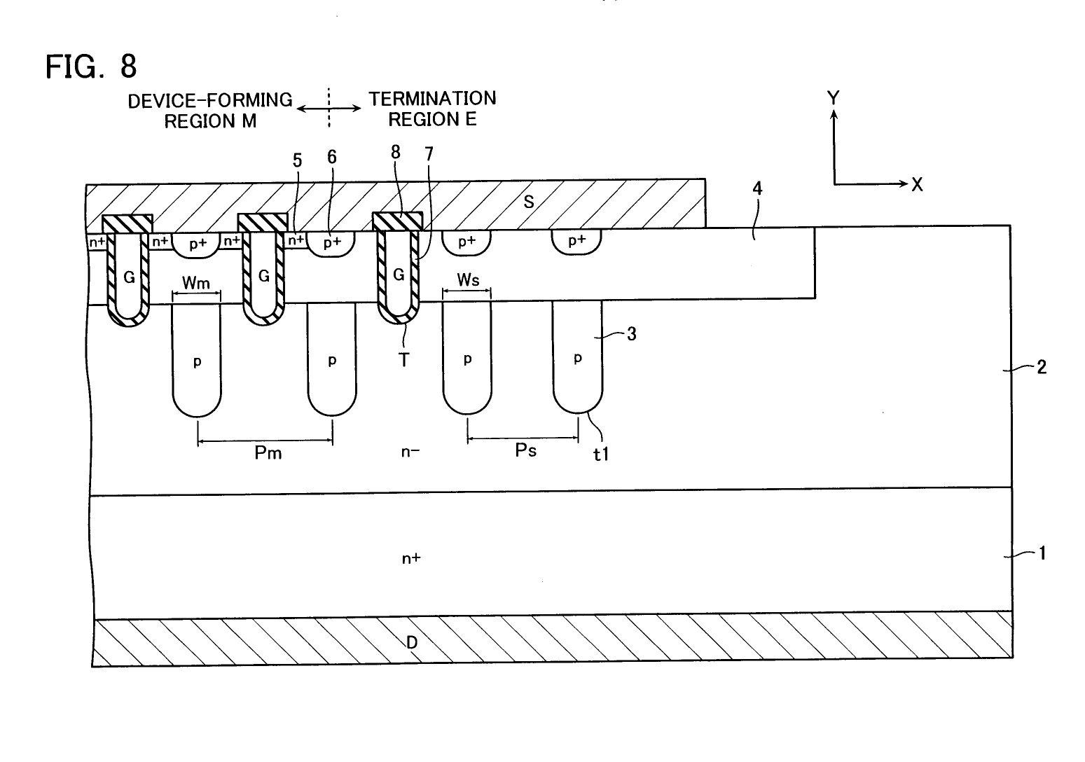

Further, as illustrated in FIG. 8, the net charge balance in the termination region E may be imbalanced in comparison to the net charge balance in the device-forming region M by varying the pitch Pm of the p-type column layer 3 in the device-forming region M and the pitch Ps of the p-type column layer 3 in the termination region E.

Further, the present invention may be applied in any super junction structure with p-type column layers and portions of n-type column layer being alternately and repeatedly positioned adjacent to each other, and not limited to such structures of the p-type and n-type column layers as illustrated in this embodiment. The present invention may also be made according to similar process steps as commonly used in making MOS transistors with a super junction structure. That is, the process of manufacture may be modified in various ways as long as the device is made as follows: with respect to the net charge balance in the device-forming region M and the termination region E between the p-type column layer and the n-type column layer, the net charge balance between the p-type column layer formed in connection with the base layer and the n-type column layer in the termination region E, in which no source layer is formed, becomes imbalanced in comparison to the net charge balance between the p-type column layer and the n-type column layer in the device-forming region M.

For example, the net charge balance in the termination region E may be imbalanced in comparison to the net charge balance in the device-forming region M by varying the impurity concentration for the device-forming region M and the termination region E. In this case, for the impurity concentration, ion implantation may be performed so that the p-type impurity concentration becomes larger than the n-type impurity concentration, or vice versa.

Further, the net charge balance in the termination region E may be imbalanced in comparison to the net charge balance in the device-forming region M by varying the pitch Pm of the p-type column layer 3 in the device-forming region M and the pitch Ps of the p-type column layer 3 in the termination region E. This may be achieved by adjusting each array pitch of the aperture a1 and a2 at the step of forming an aperture in the mask illustrated in FIG. 6. As described above, in the method for making a semiconductor device according to this embodiment, the balance of the net charge amount of the impurity between the second conductivity type layer and the first conductivity type layer in the termination region may be imbalanced in comparison to the balance of the net charge amount of the impurity between the second conductivity type layer and the first conductivity type layer in the device-forming region, providing a difference between the array pitch of a first aperture formed in the processing film on the device-forming region and the array pitch of a second aperture formed in the processing film on the termination region.

### Second Embodiment

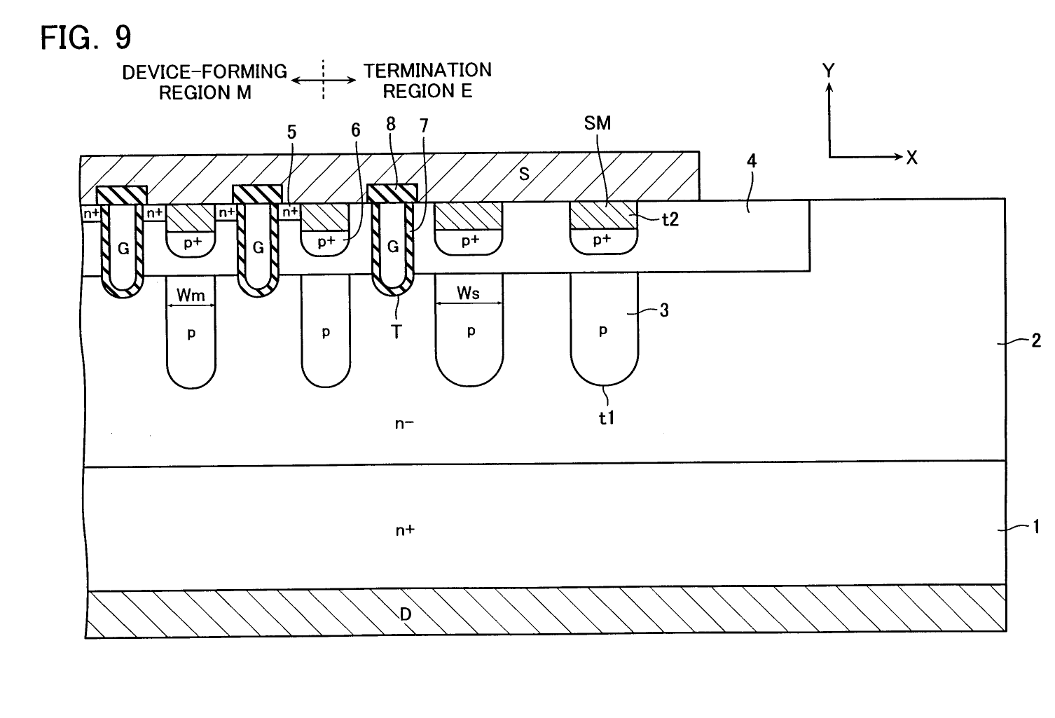

Now, a second embodiment of the present invention will be described below with reference to FIG. 9, etc. The second embodiment is different from the first embodiment in that the p⁺ type high concentration layer 6 of the first embodiment is embedded and formed in a trench t2 provided on the p-type base layer 4, on which a source metal SM is further provided.

FIG. 9 illustrates a longitudinal sectional view of a semiconductor device according to a second embodiment of the present invention. This longitudinal sectional view illustrates, similar to the first embodiment, a termination region E of the semiconductor device.

The semiconductor device has a trench t2 formed on a p-type base layer 4, in which a p⁺ type high concentration layer 6 is formed. Further, a source metal SM is deposited on the p⁺ type high concentration layer 6. In addition, in the device-forming region M, an n⁺ type source layer 5 is located on the right and left side of the source metal SM. The n⁺ type source layer 5 contacts with the source metal SM. In addition, other configurations are substantially the same as the first embodiment, and the explanation of which will be omitted by giving same reference numerals as in the first embodiment.

In the semiconductor device so configured, for example, the process steps are repeated until the p-type base layer 4 is formed in a similar way to the above-mentioned methods for making the semiconductor device according to the first embodiment of the present invention. Then, an oxide film is deposited on the surface of the p-type base layer 4 for patterning, and etching is performed to form a trench t2. Then, the device may be made by forming the p⁺ type high concentration layer 6 in the trench t2 by an epitaxial growth method and depositing the source metal SM on the p⁺ type high concentration layer 6 by sputtering.

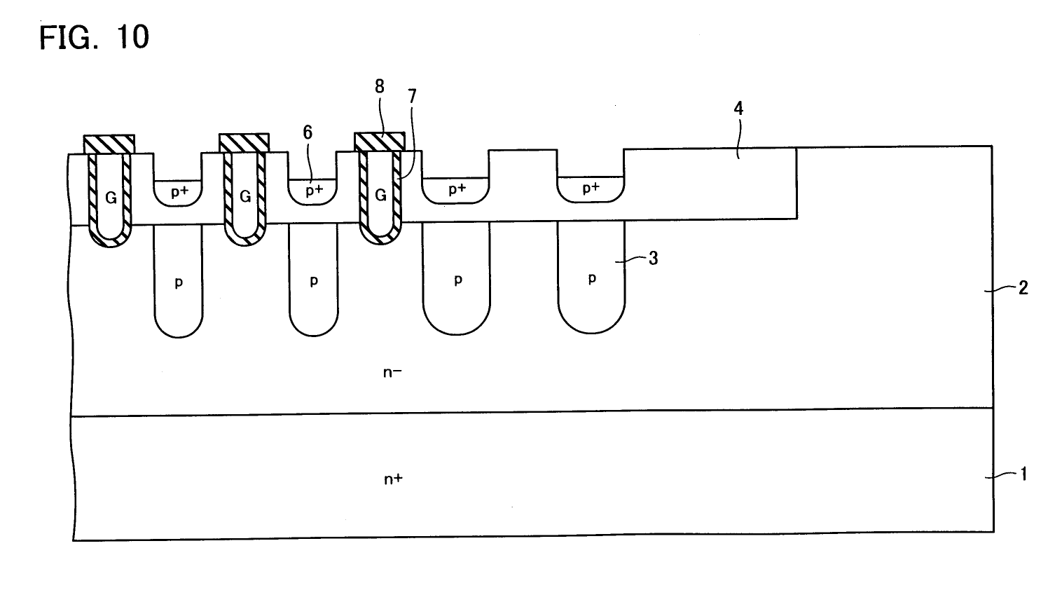

Then, another method for making the semiconductor device according to the second embodiment of the present invention will be described below with reference to the drawings. FIG. 10 is a process diagram illustrating a method for making a trench MOS transistor according to the second embodiment of the present invention. The method for making the semiconductor device according to the second embodiment is similar to the method for making the semiconductor device according to the first embodiment of the present invention until the step of forming the oxide film 11 illustrated in FIG. 6.

After an oxide film 11 is formed, the oxide film 11 is used as a mask and ion implantation is performed into an n⁻ type epitaxial layer 2. Further, using the oxide film 11 as a mask, a trench t2 is formed in a p-type base layer 4. Then, ion implantation is performed into the p-type base layer 4 from the bottom of the trench t2. After the oxide film 11 is removed, a p-type column layer 3 is formed in the n⁻ type epitaxial layer 2, and a p⁺ type high concentration layer 6 is formed in the p-type base layer 4, e.g., by diffusing ion by heating process (see FIG. 10).

Then, ion implantation is performed into the p-type base layer 4 in the device-forming region M, on which the n⁺ type source layer 5 is selectively formed. After that, a source electrode is sputtered on the p-type base layer 4 including the inside of the trench t2 and etching is performed to form a source electrode S and a source metal SM. In addition, after the rear surface of the n⁺ type semiconductor substrate 1 is polished, a drain electrode D is provided accordingly. The semiconductor device illustrated in FIG. 9 may also be made according to the above-mentioned method.

As such, providing the source metal SM inside the trench t2 as well, a larger contact area between the n⁺ type source layer 5 and the source electrode S may be obtained, and on-resistance may also be reduced accordingly.

### Third Embodiment

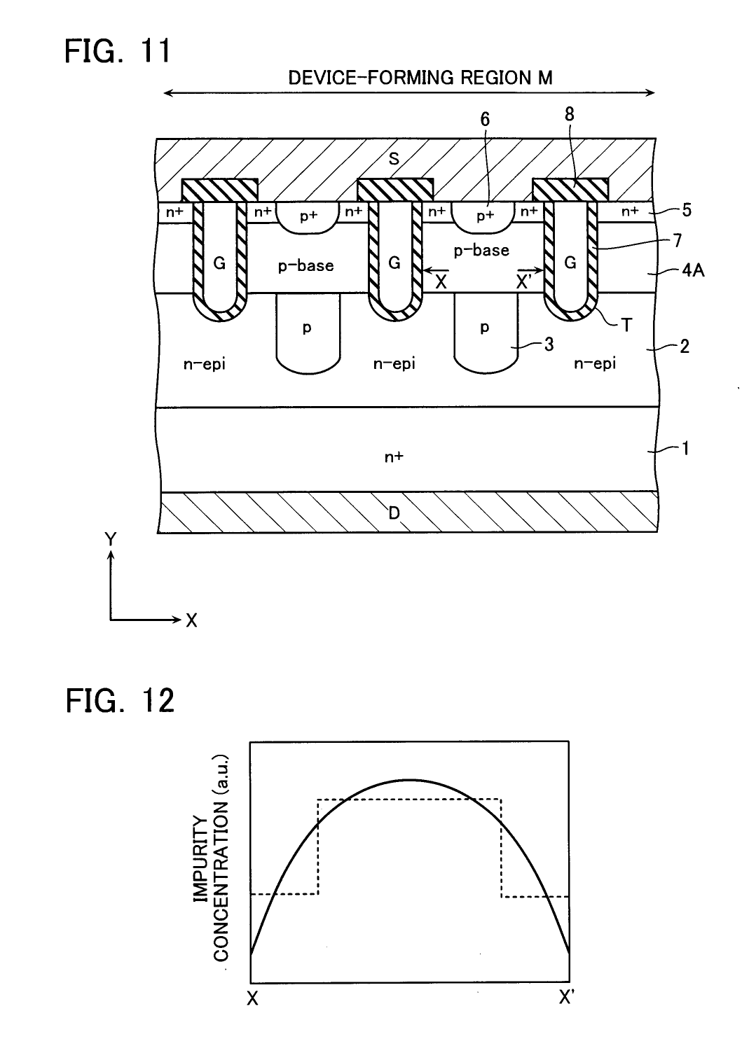

Now, a third embodiment of the present invention will be described below with reference to FIG. 11, etc. The third embodiment provides a semiconductor device with another configuration for improving the avalanche withstanding capability. The semiconductor device according to the third embodiment of the present invention is characterized in that the impurity concentration of the p-type base layer 4A is changed in the device-forming region M.

FIG. 11 illustrates a longitudinal sectional view of the device-forming region M. In addition, FIG. 12 illustrates the impurity concentration distribution at X-X′ cross-section of FIG. 11.

The semiconductor device has an n⁻ type epitaxial layer 2 formed on an n⁺ type semiconductor substrate 1. Provided on the n⁻ type epitaxial layer 2 are p-type column layers 3 that are repeatedly formed in a column-like fashion. Further, a p-type base layer 4A is formed on the n⁻ type epitaxial layer 2 in which the p-type column layers 3 are formed. In addition, an n⁺ type source layer 5 and a p⁺ type high concentration layer 6 are selectively formed on a surface of the p-type base layer 4A. Further, a trench is formed on the surface of the p-type base layer 4A that extends to the inside of the epitaxial layer 2. A gate insulation film 7 is formed on the side surfaces and the bottom surface of the trench. A gate electrode G is embedded inside the gate insulation film 7. Further, an interlayer insulating film 8 is formed on the gate electrode G. A source electrode S is formed on the p-type base layer 4A so as to contact with the n⁺ type source layer 5. A drain electrode D is formed on the bottom surface of the n⁺ type semiconductor substrate 1.

Further, as illustrated by the full line of FIG. 12, the impurity concentration of the p-type base layer 4A between two trenches T is configured to increase gradually as far from the trench T. That is, the impurity concentration of the p-type base layer 4A has a mountainous concentration distribution with its peak in the middle of two trenches T.

In such semiconductor devices, it would be difficult for any generated hole to be injected into the n⁺ type source layer 5, since the broke-down current, which is generated at the time of turn-off, causes impact ionization in a region more distant from the trench T that has higher impurity concentration. As a result, it would also be difficult for the bipolar transistor with an n-p-n junction to be turned “ON” that includes the n⁺ type source layer 5, p-type base layer 4 and n⁺ type semiconductor substrate 1 as an emitter, base and collector, respectively, thereby improving the avalanche withstanding capability in the semiconductor device.

Further, although the third embodiment may improve the avalanche withstanding capability independently, it may configure the semiconductor device in combination with the first embodiment. That is, the semiconductor device may be configured in such a way that the net charge balance becomes imbalanced in the termination region E, while the concentration of the p-type base layer 4 between the trenches T grows higher as far from the trench T in the device-forming region M. This may further improve the avalanche withstanding capability in the entire semiconductor device.

In addition, according to the third embodiment, as illustrated by the full line of FIG. 12, although the p-type impurity concentration of the p-type base layer 4A is configured to be gradually changed in a mountainous fashion, it may also be possible to change the p-type impurity concentration in a step-like fashion with a maximum concentration in the middle of the trenches T, as illustrated by the dashed line of FIG. 12.

What is claimed is:

1. A semiconductor device comprising:
a first conductivity type layer and a second conductivity type layer, each being alternately and repeatedly positioned, adjacent to each other, in a column-like fashion on a first conductivity type substrate;
a second conductivity type base layer formed on the first conductivity type layer and the second conductivity type layer;
a trench formed so as to extend from a surface of the second conductivity type base layer to the first conductivity type layer;
a gate insulation film formed on the side surfaces and the bottom surface of the trench;
a gate electrode formed inside the trench via the gate insulation film;
an interlayer insulating film formed on the gate electrode;
a first conductivity type diffusion layer formed on the surface of the second conductivity type base layer;
a first main electrode formed on the first conductivity type diffusion layer;
a second main electrode formed on the bottom surface of the first conductivity type substrate;
a device-forming region in which the first conductivity type diffusion layer is formed; and
a termination region provided around the circumference of the device-forming region and not including the first conductivity type diffusion layer formed therein,
wherein the balance of the net charge amount of the impurity between the first conductivity type layer formed under the second conductivity type base layer in the termination region and the second conductivity type layer adjacent to the first conductivity type layer is imbalanced in comparison to the balance of the net charge amount of the impurity between the first conductivity type layer in the device-forming region and the second conductivity type layer adjacent to the first conductivity type layer.

2. The semiconductor device according to claim 1, wherein
the imbalance of the net charge amount of the impurity between a first conductivity type layer in the termination region and a second conductivity type layer adjacent to the first conductivity type layer is determined, in comparison to the balance of the device-forming region, by providing a difference between the width of the second conductivity type layer in the termination region and the width of the second conductivity type layer in the device-forming region.

3. The semiconductor device according to claim 1, wherein
the imbalance of the net charge amount of the impurity between a first conductivity type layer in the termination region and a second conductivity type layer adjacent to the first conductivity type layer is determined, in comparison to the balance of the device-forming region, by providing a difference between the array pitch of the second conductivity type layer in the termination region and the array pitch of the second conductivity type layer in the device-forming region.

4. The semiconductor device according to claim 1, wherein
the imbalance of the net charge amount of the impurity between a first conductivity type layer in the termination region and a second conductivity type layer adjacent to the first conductivity type layer is determined, in comparison to the balance of the device-forming region, by providing a difference between the impurity concentration of the second conductivity type layer in the termination region and the impurity concentration of the second conductivity type layer in the device-forming region.

5. The semiconductor device according to claim 1, further comprising:
a contacting trench provided in the second conductivity type base layer;
wherein the first main electrode is also formed inside the contacting trench.

6. A method for making a semiconductor device comprising:
forming a first conductivity type layer on a first conductivity type substrate by epitaxial growth;
forming a second conductivity type base layer by injecting and diffusing second conductivity type impurity into a surface of the first conductivity type layer;
forming a trench so as to extend from the surface of the second conductivity type base layer to the first conductivity type layer;
forming a gate insulation film on the side surfaces and the bottom surface of the trench;
forming a gate electrode inside the trench via the gate insulation film;
forming an interlayer insulating film on the gate electrode;
depositing a processing film over the first conductivity type layer in which the second conductivity type base layer is formed;
forming a first aperture in the processing film on a device-forming region, and forming a second aperture in the processing film on a termination region provided around the circumference of the device-forming region;
performing ion implantation on the first conductivity type layer, so that the balance of the net charge amount of the impurity between a second conductivity type layer formed under the second conductivity type base layer in the termination region using the processing film as a mask and the first conductivity type layer adjacent to the second conductivity type layer becomes imbalanced in comparison to the balance of the net charge amount of the impurity between a second conductivity type layer formed under the second conductivity type base layer in the device-forming region and the first conductivity type layer adjacent to the second conductivity type layer;
performing ion implantation on the second conductivity type base layer on the device-forming region to form a first conductivity type diffusion layer;
forming a first main electrode on the first conductivity type diffusion layer; and
forming a second main electrode on the bottom surface of the first conductivity type substrate.

7. The method for making a semiconductor device according to claim 6, wherein
the balance of the net charge amount of the impurity between the second conductivity type layer and the first conductivity type layer in the termination region becomes imbalanced in comparison to the balance of the net charge amount of the impurity between the second conductivity type layer and the first conductivity type layer in the device-forming region, by providing a difference between the array pitch of a first aperture formed in the processing film on the device-forming region and the array pitch of a second aperture formed in the processing film on the termination region.

8. The method for making a semiconductor device according to claim 6, wherein
the balance of the net charge amount of the impurity between the second conductivity type layer and the first conductivity type layer in the termination region becomes imbalanced in comparison to the balance of the net charge amount of the impurity between the second conductivity type layer and the first conductivity type layer in the device-forming region, by providing a difference between a first width of a first aperture formed in the processing film on the device-forming region and a second width of a second aperture formed in the processing film on the termination region.

9. The method for making a semiconductor device according to claim 6, wherein
the balance of the net charge amount of the impurity between the second conductivity type layer and the first conductivity type layer in the termination region becomes imbalanced in comparison to the balance of the net charge amount of the impurity between the second conductivity type layer and the first conductivity type layer in the device-forming region, by providing a difference between the impurity concentration of the second conductivity type layer in the device-forming region and the impurity concentration of the second conductivity type layer in the termination region.

10. The method for making a semiconductor device according to claim 6, further comprising:
forming a contacting trench in the second conductivity type base layer using the processing film as a mask, the processing film having the first and second apertures; and
forming the first main electrode on the first conductivity type diffusion layer including the inside of the contacting trench.

11. A semiconductor device comprising:
a first conductivity type layer and a second conductivity type layer, each being alternately and repeatedly positioned, adjacent to each other, in a column-like fashion on a first conductivity type substrate;
a second conductivity type base layer formed on the first conductivity type layer and the second conductivity type layer;
a trench formed so as to extend from a surface of the second conductivity type base layer to the first conductivity type layer;
a gate insulation film formed on the side surfaces and the bottom surface of the trench;
a gate electrode formed inside the trench via the gate insulation film;
an interlayer insulating film formed on the gate electrode;
a first conductivity type diffusion layer formed on the surface of the second conductivity type base layer;
a first main electrode formed on the first conductivity type diffusion layer;
a second main electrode formed on the bottom surface of the first conductivity type substrate;
a device-forming region in which the first conductivity type diffusion layer is formed; and
a termination region provided around the circumference of the device-forming region and not including the first conductivity type diffusion layer formed therein;
wherein the second conductivity type base layer in the device-forming region has a higher second conductivity type impurity concentration in a position far from the trench than in the vicinity of the trench.

12. The semiconductor device according to claim 11, wherein
the impurity concentration of the second conductivity type base layer has a concentration distribution with a substantially maximum concentration in the substantially middle of the trench.
